(19) United States
(12) Patent Application Publication
(10) Pub. No.: US 2001/0018894 A1
(43) Pub. Date: Sep. 6, 2001

(54) Vertical low-pressure chemical vapor deposition furnace

(76) Inventor: Ching-Yu Chang, Yilan Hsien (TW)

Correspondence Address: J.C. Patents, Inc., Suite 114, 1340 Reynolds Ave., Irvine, CA, 92614, US

(21) Appl. No.: 09/727,125

(22) Filed: Nov. 30, 2000

(30) Foreign Application Priority Data
Feb. 15, 2000 (TW) 89102487

(51) Int. Cl. C23C 16/46

(52) U.S. Cl. 118/724

(57) ABSTRACT

A vertical low-pressure chemical vapor deposition furnace. The furnace includes an outer quartz tube, a heating device and a gas injector. The heating device is installed on the exterior sidewalls of the outer quartz tube for heating the quartz tube. The gas injector includes an entrance section, a looping main body and an outlet section. The input section penetrates a hole on the lower sidewall of the outer quartz tube. The looping main body is positioned between the outer quartz tube and a quartz boat. One end of the looping main body is connected to the input section while the other end is connected to the output section. Reactive gases flowing into the input section is preheated in the looping main body before delivering into the reaction chamber.

### CROSS-REFERENCE TO RELATED APPLICATION

This application claims the priority benefit of Taiwan application Ser. No. 89102487, filed Feb. 15, 2000.

### BACKGROUND OF THE INVENTION

1. Field of Invention

The present invention relates to a chemical vapor depositing station. More particularly, the present invention relates to a vertical low-pressure chemical vapor deposition (LPCVD) furnace.

2. Description of Related Art

Chemical vapor deposition (CVD) is a major thin film deposition method in semiconductor production. According to the deposition pressure, CVD can be divided into atmospheric pressure CVD (APCVD) and low pressure CVD (LPCVD). In LPCVD, the process is carried out at a pressure below 100 Torrs and hence the thin films have good step coverage. Thus, LPCVD is the popular method for forming thin films on semiconductor substrates.

The reactor necessary for carrying out LPCVD can be fitted inside a vertical furnace. Because overall volume occupation of a vertical furnace is smaller than a conventional horizontal LPCVD furnace, vertical furnaces gradually replace the conventional horizontal furnaces.

FIG. 1 is a schematic cross-sectional view of a conventional vertical LPCVD furnace. As shown in FIG. 1, a vertical LPCVD furnace belongs to a hot-wall reaction type of thin film depositor. The reactor is an annealed quartz tube 102. Outside and surrounding the quartz tube 102 is a group of heating elements 108 for heating up the furnace. Since the group of heating elements 108 has altogether five sections, the group of heating elements 108 is also called a ‘five-zone heater’. Reactive gases from outside passes into the reaction chamber through a gas injector 110. The wafers waiting for thin film deposition are mounted on a quartz boat 104 and the quartz board 104 is placed in a suitable position inside the quartz tube 102.

The gas injector 110 of the vertical LPCVD furnace is located at the lower end of the quartz tube 102 so that reactive gases from outside can be directly injected into the quartz tube 102. However, the reactive gases from outside has a pressure of about 760 Torrs and a temperature of about 25° C. On the other hand, the pressure inside the quartz tube 12 is only about 0.5 Torr while the temperature is very high at about 535° C. Hence, a large amount of heat will be absorbed by incoming the reactive gases as the reactive gases are diffused from the lower section to the middle and top section of the quartz chamber. In general, the rate of chemical deposition is highly dependent upon gaseous temperature. To prevent non-uniformity of deposited film due to heat absorption of incoming gases, the heating elements closer to the lower section is normally powered up a little just to compensate for the heat loss due to heat absorption.

For example, in a furnace controlled to about 535° C., heating elements 108 in the first region 114, the second region 116 and the third region 118 are maintained at a temperature of about 535° C. The heating element 108 in the fourth region 120 has to be heated to a temperature of about 538° C. while the heating element 108 in the fifth region 122 has to be heated to a temperature about 543° C.

Although raising temperature at the lower section of the furnace is capable of compensating for heat loss resulting from the transfer of reactive gases from outside into the quartz chamber 102, the reactive gases may be overheated. For a highly temperature dependent process such as growing hemispherical silicon grains (HSG) or forming an amorphous silicon layer, overheating the reactive gases may affect size of the grains or quality of the amorphous silicon layer. Therefore, product yield may be affected.

### SUMMARY OF THE INVENTION

Accordingly, one object of the present invention is to provide a vertical low-pressure chemical vapor deposition (LPCVD) furnace capable of preventing the formation of non-uniform film layers due to a top to bottom temperature gradient inside a conventional furnace.

A second object of the invention is to provide a vertical LPCVD furnace capable of maintaining a constant temperature throughout the reaction chamber of the furnace during chemical deposition.

A third object of the invention is to provide a vertical LPCVD furnace capable of meeting stringent demands for temperature range.

To achieve these and other advantages and in accordance with the purpose of the invention, as embodied and broadly described herein, the invention provides a vertical LPCVD furnace. The furnace includes an outer quartz tube, a group of heating elements and a gas injector. The group of heating elements is installed on the exterior sidewalls of the outer quartz tube for heating the quartz tube. The gas injector includes an entrance section, a looping main body and an outlet section. The input section penetrates a hole on the lower sidewall of the outer quartz tube. The looping main body is positioned within the outer quartz tube. One end of the looping main body is connected to the input section while the other end is connected to the output section. Therefore, gases flowing from outside via the input section, the looping main body and the output section are preheated by the outer quartz tube before entering the quartz chamber.

According to the aforementioned embodiment of this invention, the vertical LPCVD furnace further includes a quartz boat, a set of inner quartz tubes and a group of thermocouples. The quartz boat is placed inside the outer quartz tube for holding silicon wafers inside the quartz chamber. The set of inner quartz tubes is mounted on the interior sidewalls of the outer quartz tube. The looping main body of the gas injector is positioned either between the quartz boat and the inner quartz tube or between the inner quartz tube and the outer quartz tube. The group of thermocouples measures temperatures at various points of the furnace. The thermocouples may be enclosed inside the inner quartz tube, attached to the outside of the inner quartz tube, or attached to the sidewalls of the outer quartz tube.

In this invention, the gas injector has a looping structure with the looping main body sandwiched between the quartz boat and the outer quartz tube for preheating the reactive gases before entering the quartz chamber. Therefore, non-uniformity of film layers caused by a temperature gradient from the top to the bottom of a conventional furnace is prevented. Since a constant temperature is maintained throughout the reaction chamber of the vertical furnace during a reaction, the most stringent temperature conditions can be met.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings, FIG. 1 is a schematic cross-sectional view of a conventional vertical LPCVD furnace;

FIG. 2 is a schematic cross-sectional view of a vertical LPCVD furnace according to one preferred embodiment of this invention;

FIG. 3 is a magnified view of the gas injector shown in FIG. 2; and

Table 1 is a listing of the temperatures at the five heating zones of a vertical LPCVD furnace according to this invention and the temperatures at the five corresponding heating zones of a conventional LPCVD furnace.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

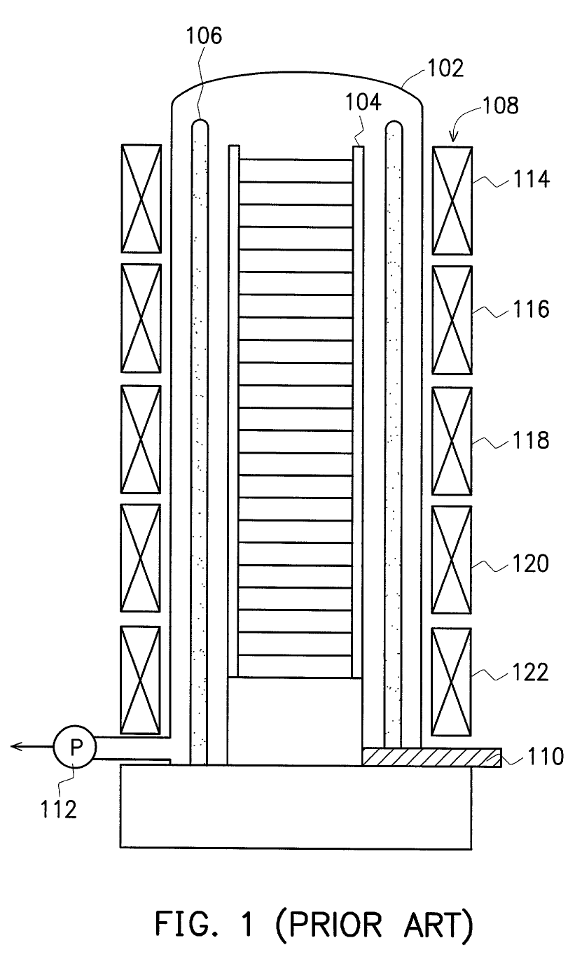

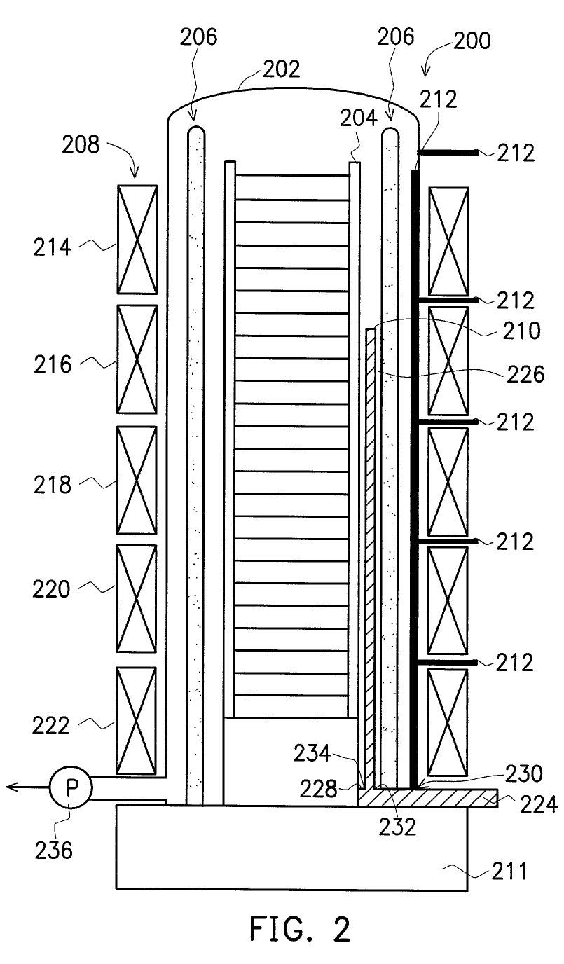

FIG. 2 is a schematic cross-sectional view of a vertical LPCVD furnace according to one preferred embodiment of this invention. As shown in FIG. 2, the vertical low-pressure chemical vapor deposition (LPCVD) furnace 200 of this invention includes an outer quartz tube 202, an inner quartz tube 206, a heating device 208, a gas injector 210 and a group of thermocouples 212. The outer quartz tube 202 serves as a reaction chamber for chemical vapor deposition (CVD). The outer quartz tube 202 encloses a quartz boat 204 and the inner quartz tube 206. The quartz boat 204 is put on top of rising platform 211. The quartz boat 204 is a holder for laying silicon wafers horizontally so that low-pressure chemical vapor deposition can take place on wafer surfaces. The quartz inner tube 206 is positioned inside the outer quartz tube 202 such that reactive gases is able to flow smoothly from the bottom of the quartz boat 204 up to the top of the furnace 200. The upward flowing gases reacts chemically with the wafers to form uniform thin films. Residual gases after the reaction are passed from the top of the furnace 200 into the space between the inner quartz tube 206 and the outer quartz tube 202 and then exhausted via a pump 236.

The heating device 208 is on the exterior sidewalls of the outer quartz tube 202 for heating up the furnace 200. Preferably, the heating device 208 includes at least five sections, namely 214, 216, 218, 220 and 222 so that each section of the furnace 200 can be independently heated and an optimal furnace temperature distribution can be obtained. With an optimal furnace temperature distribution, a uniformly thick film layer is able to form on all wafers on the quartz boat 204 independent of their locations.

The group of thermocouples 212 monitors temperature in the furnace 200. When furnace temperature as measured by the thermocouples 212 is different from preset temperatures, a power controller will adjust the power supplied to the heating device 208 so that the optimal values are obtained. The group of thermocouples 212 can be temperature profiling thermocouples or spike thermocouples. The temperature profiling thermocouples is preferably installed on the inside of the outer quartz tube 202, for example, the inside of the outside of the inner quartz tube 206 for measuring the core temperature of the furnace 200. The spike thermocouples are preferably positioned on the exterior of the outer quartz tube 202 for measuring sidewall temperatures in the five heating sections of the furnace 200.

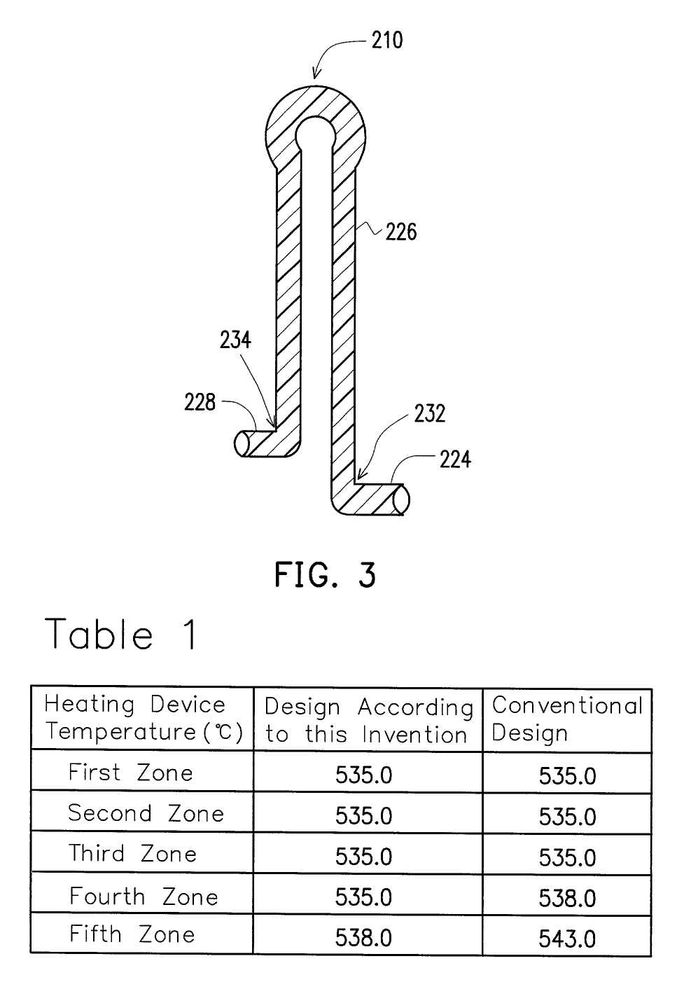

The gas injector 210 is responsible for delivering reactive gases from outside into the interior of the furnace 200. FIG. 3 is a magnified view of the gas injector shown in FIG. 2. As shown in FIGS. 2 and 3, the gas injector 210 includes an entrance section 224, a looping main body 226 and an outlet section 228. The entrance section 224 passes through a hole 230 on the lower sidewall of the outer quartz tube 202. The looping main body 226 is positioned inside the outer quartz tube 202 between the quartz boat 204 and the inner quartz tube 206. One end 232 of the looping main body 226 connects with the entrance section 224. The other end 234 of the looping main body 226 connects with the outlet section 228. Reactive gases is able to pass into the reaction chamber inside the outer quartz tube 202 via the entrance section 224, the looping main body 226 and the outlet section 228. The looping main body 226 extends, for example, from the bottom portion of the outer quartz tube 202 up via sections 222, 220 and 218 of the heating device 208 into the middle section of the outer quartz tube 202. The looping main body then turns around going down via sections

In this invention, the gas injector 210 has a looping structure with the looping main body 226 sandwiched between the quartz boat 204 and the outer quartz tube 202. For example, the looping main body 226 can be inserted in a location between the quartz boat 204 and the inner quartz tube 206 or between the inner quartz tube 206 and the outer quartz tube 202. Ultimately, the reactive gases are preheated by the heating device 208 before entering the quartz chamber.

The looping main body 226, for example, can have a U-shape, an M-shape or other variations depending on the furnace design.

Table 1 is a listing of the temperatures at the five heating zones of a vertical LPCVD furnace according to this invention and the temperatures at the five corresponding heating zones of a conventional LPCVD furnace.

TABLE 1

| Heating Device | Design According | Conventional |
|---|---|---|
| Temperature (° C.) | to this Invention | Design |
| First Zone | 535.0 | 535.0 |
| Second Zone | 535.0 | 535.0 |
| Third Zone | 535.0 | 535.0 |
| Fourth Zone | 535.0 | 538.0 |
| Fifth Zone | 538.0 | 543.0 |

Table 1 is a listing of the temperatures at the five heating zones of a vertical LPCVD furnace having a U-shaped looping gas injector according to this invention and the temperatures at the five corresponding heating zones of a conventional LPCVD furnace. As shown in Table 1, for a conventional furnace design, temperature in zone four of the furnace is higher than zone one to three by three degrees Celsius and temperature in zone five is higher by eight degrees Celsius. For the furnace of this invention, temperature in zone four is identical to temperature in zone one to three (at furnace due to temperature variation. In fact, the invention is able to maintain a very constant temperature inside the reaction chamber and hence the furnace is suitable for performing whatever reactions that requires a highly stringent temperature condition.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A vertical low-pressure chemical vapor deposition (LPCVD) furnace, comprising:
an outer quartz tube having a hole near the bottom of the sidewall;
a heating device around the exterior sidewall of the outer quartz tube for heating the outer quartz tube; and
a gas injector having an entrance section, a looping main body and an outlet section, wherein the entrance section passes through the hole, the looping main body is inside the outer quartz tube and extends into a portion of the heating device, one end of the loop main body connects with the entrance section while the other end connects with the outlet section so that reactive gases passing into the gas injector from the entrance section can be preheated before delivering to the reaction chamber inside the outer quartz tube via the outlet section.

2. The vertical LPCVD furnace of claim 1, wherein the furnace further includes:
a quartz boat placed inside the outer quartz tube for mounting a plurality of wafers; and
an inner quartz tube placed inside the outer quartz tube for make a laminar flow of the furnace.

3. The vertical LPCVD furnace of claim 2, wherein the looping main body of the gas injector is positioned between the quartz boat and the inner quartz tube.

4. The vertical LPCVD furnace of claim 2, wherein the looping main body of the gas injection is positioned between the outer quartz tube and the inner quartz tube.

5. The vertical LPCVD furnace of claim 1, wherein the looping main body of the gas injector has an inverted U-shape.

6. The vertical LPCVD furnace of claim 1, wherein the looping main body of the gas injector has a letter M-shape.

7. The vertical LPCVD furnace of claim 1, wherein the heating device includes five elements capable of heating various parts of the outer quartz tube independently.

8. The vertical LPCVD furnace of claim 1, wherein the furnace further includes a group of thermocouples positioned inside the outer quartz tube for measuring furnace temperature.

9. The vertical LPCVD furnace of claim 8, wherein the group of thermocouples includes a group of profiling thermocouples.

10. The vertical LPCVD furnace of claim 1, wherein the furnace further includes a group of thermocouples positioned on the outer sidewall of the outer quartz tube for measuring furnace temperature.

11. The vertical LPCVD furnace of claim 10, wherein the group of thermocouples includes a group of spike thermocouples.

12. A vertical low-pressure chemical vapor deposition (LPCVD) furnace, comprising:
an outer quartz tube having a hole near the bottom of the sidewall;
a heating device around the exterior sidewall of the outer quartz tube for heating the furnace;
a quartz boat positioned inside the outer quartz tube for mounting a plurality of wafers;
an inner quartz tube positioned on the inner sidewall of the outer quartz tube for laminar flow control;
a gas injector having an entrance section, a looping main body and an outlet section, wherein the entrance section passes through the hole, the looping main body is inside the outer quartz tube and extends into a portion of the heating device, one end of the loop main body connects with the entrance section while the other end connects with the outlet section so that reactive gases passing into the gas injector from the entrance section can be preheated before delivering to the reaction chamber inside the outer quartz tube via the outlet section; and
a group of thermocouples positioned inside the outer quartz tube for measuring furnace temperature.

13. The vertical LPCVD furnace of claim 12, wherein the outer quartz tube is divided into a first zone, a second zone, a third zone, a fourth zone and a fifth zone from the top to the bottom of the outer quartz tube, and the heating device has a heating element in each of the five zones for independent heating.

14. The vertical LPCVD furnace of claim 12, wherein the looping main body of the gas injector extends from the fifth zone up to at least the fourth zone and then turns around back to the fifth zone.

15. The vertical LPCVD furnace of claim 12, wherein the group of thermocouples includes a group of profiling thermocouples.
